(19) United States
(12) Patent Application Publication
(10) Pub. No.: US 2024/0182769 A1
(43) Pub. Date: Jun. 6, 2024

(54) HEAT SINK PASTE, HEAT SINK FILM AND MANUFACTURING METHODS THEREFOR

(71) Applicant: Foundation for Research and Business, Seoul National University of Science and Technology, Seoul (KR)

(72) Inventors: Hyung Jun KOO, Seoul (KR); Ji Hye KIM, Seoul (KR); Akyildiz KUBRA, Seoul (KR)

(73) Assignee: Foundation for Research and Business, Seoul National University of Science and Technology, Seoul (KR)

(21) Appl. No.: 18/285,507

(22) PCT Filed: Oct. 29, 2021
(86) PCT No.: PCT/KR2021/015410

§ 371 Date: Oct. 4, 2023

(30) Foreign Application Priority Data
Jul. 29, 2021 (KR) 10-2021-0100145

(51) Int. Cl. C09K 5/14; C08J 5/18; C08K 3/08; C09K 5/10

(52) U.S. Cl. CPC C09K 5/14; C08J 5/18; C08K 3/08; C09K 5/10; C08J 2383/04; C08K 2003/085; C08K 2201/001; C08K 2201/005; C08K 2201/011; C08K 2201/014

(57) ABSTRACT

The present disclosure relates to a heat sink paste, a heat sink film and manufacturing methods therefor. The heat sink paste according to an embodiment of the present disclosure includes an elastic polymer resin and conductive particles dispersed in the elastic polymer resin, wherein the conductive particles include solid metal particles and liquid metal particles.

### TECHNICAL FIELD

The present disclosure relates to a heat sink paste (heat dissipation paste), a heat sink film (heat dissipation film), and manufacturing methods thereof.

### DESCRIPTION OF RELATED ART

When advanced communication and digital electrical and electronic products operate, various parts that are slimmed and mounted on main boards fail to efficiently conduct or dissipate heat generated inside electrical and electronic products or to shield noise, due to light, thin, and compact structures thereof. In this case, issues such as malfunctions, a degradation of functions, and a reduction in life span of electronic devices occur.

Accordingly, a great deal of interest and research is being focused on technology of controlling dissipated heat of an electronic device. In particular, a high heat dissipation substrate material is effectively applicable to manufacturing of parts that consume a significantly large amount of power and generate a large amount of heat.

In general, a high thermally conductive filler such as a ceramic material or a carbon material is used as a heat dissipation material, for a high thermal conductivity. However, as a large amount of filler is added to increase the thermal conductivity, a flexibility of a composite material is affected by materials having a high modulus of elasticity, which makes it difficult to satisfy a processing condition and leads to a deterioration in physical properties of a product.

In addition, since a heat dissipation composite is prepared by a simple mixing scheme and conductive fillers in the composite are randomly arranged without directivity, heat dissipation performance is less than expected performance or it is difficult to expect reproducible heat dissipation performance.

Therefore, it is difficult to apply heat dissipation and heat transfer composites in terms of their properties such as flexibility, self-healing, and electrical insulation.

### DISCLOSURE OF THE INVENTION

### Technical Goals

The present disclosure is to solve the above problems, and an aspect of the present disclosure is to provide a heat sink paste (heat dissipation paste) and a heat sink film (heat dissipation film) that have an elasticity and have excellent heat dissipation effect without a decrease in a thermal conductivity, and to provide methods of manufacturing the same.

However, the technical goal obtainable from the present disclosure is not limited to those described above, and other goals not mentioned above can be clearly understood by one of ordinary skill in the art to which the present disclosure pertains from the following description.

### Technical Solutions

A heat sink paste (heat dissipation paste) according to an embodiment of the present disclosure includes an elastic polymer resin; and conductive particles dispersed in the elastic polymer resin, wherein the conductive particles include solid metal particles and liquid metal particles.

In an embodiment, the elastic polymer resin may include at least one selected from a group consisting of polyacrylate rubber (ACM), ethylene acrylic rubber (AEM), polyurethane (PU), butadiene rubber (BR), chloroprene (or neoprene) rubber (CR), chlorosulfonated polyethylene (CSM), ethylene oxide epichlorohydrin rubber (ECO), ethylene propylene diene rubber (EPDM), perfluoroelastomer (FFKM), fluorocarbon rubber (FKM), fluorosilicone rubber (FVMQ), hydrogenated nitrile butadiene rubber (HNBR), isoprene rubber (IR), butyl rubber (IIR), nitrile butadiene rubber (NBR), natural rubber (NR), polydimethylsiloxane (PDMS), styrene butadiene rubber (SBR), silicone rubber (VMQ). Ecoflex, silicone elastomers, polyimide, polyethylene isopthalate (PEI), polyethylene naphthalate (PEN), polyethylene terephthalate (PET), cellulose, and a styrene-isoprene-styrene copolymer.

In an embodiment, the solid metal particles may include at least one selected from a group consisting of copper (Cu), gold (Au), platinum (Pt), silver (Ag), iron (Fe), cobalt (Co), nickel (Ni), aluminum (Al), chromium (Cr), tungsten (W), molybdenum (Mo), and titanium (Ti).

In an embodiment, the liquid metal particles may include at least one selected from a group consisting of gallium (Ga), indium (In), tin (Sn), mercury (Hg), lead (Pb), bismuth (Bi), thallium (Tl), zinc (Zn), cadmium (Cd), a eutectic gallium-indium alloy (EGaIn), a eutectic gallium-indium-tin alloy (Galinstan), gallium/lead (Ga/Pb), gallium/cadmium (Ga/Cd), gallium/bismuth (Ga/Bi), gallium/thallium (Ga/Tl), tin/silver (Sn/Ag), tin/gold (Sn/Au), tin/copper (Sn/Cu), tin/nickel (Sn/Ni), lead/antimony (Pb/Sb), lead/gold (Pb/Au), and lead/cadmium (Pb/Cd).

In an embodiment, the conductive particles may be in an amount of 10% by weight (wt %) to 90 wt % in the heat sink paste (heat dissipation paste), and a ratio of the solid metal particles:the liquid metal particles may be in a range of 1:5 to 5:1.

In an embodiment, the solid metal particles may have a diameter of 50 nanometers (nm) to 50 micrometers (μm), and the liquid metal particles may have a diameter of 50 nm to 50 μm.

A heat sink film (heat dissipation film) according to another embodiment of the present disclosure includes an elastic polymer; and conductive particles embedded in the elastic polymer, wherein the conductive particles include solid metal particles and liquid metal particles, and the solid metal particles and the liquid metal particles are arranged in a heat transfer direction by applying an electric field.

A method of manufacturing a heat sink film (heat dissipation film) according to another embodiment of the present disclosure includes steps of: applying an electric field to a heat sink paste (heat dissipation paste) according to an embodiment of the present disclosure; and curing the elastic polymer resin.

In an embodiment, in the step of applying the electric field, the electric field may be applied at an intensity ranging from 10 volts per millimeter (V/mm) to 600 V/mm for 1 second to 180 minutes.

In an embodiment, in the step of applying the electric field, a frequency ranging from 100 hertz (Hz) to 10 megahertz (MHz) may be applied for 1 second to 180 minutes.

### Effects

A heat sink paste (heat dissipation paste) according to an embodiment of the present disclosure may be used as a heat dissipation material having an excellent thermal conductivity and elasticity by curing a paste according to a desired purpose of use, because conductive particles in an elastic polymer resin may be arranged with directivity when an electric field is applied.

A heat sink film (heat dissipation film) according to an embodiment of the present disclosure may have an excellent thermal conductivity even at a high strain rate and may be changeable to a heat dissipation material with an elasticity, and thus it is possible to apply the heat sink film (heat dissipation film) to various flexible electronic devices or wearable displays.

In addition, since solid metal particles and liquid metal particles in the heat sink film (heat dissipation film) according to an embodiment of the present disclosure are encapsulated with an elastic polymer resin, the heat sink film (heat dissipation film) may exhibit electrical insulation properties when damage or leakage occurs due to an external force.

A method of manufacturing a heat sink film (heat dissipation film) according to an embodiment of the present disclosure may be used to manufacture a heat sink film (heat dissipation film) with an excellent heat dissipation effect and a maximized thermal conductivity, by arranging conductive particles with directivity, because it is possible to simply, quickly, and effectively arrange the particles through an electric field.

### BRIEF DESCRIPTION OF DRAWINGS

FIG. 1 is a diagram schematically illustrating a heat sink paste (heat dissipation paste) according to an embodiment of the present disclosure.

FIG. 2 is a diagram schematically illustrating a heat sink film (heat dissipation film) according to an embodiment of the present disclosure.

FIG. 3 is a diagram illustrating an example of a state before an electric field is applied to a heat sink paste (heat dissipation paste) according to an embodiment of the present disclosure.

FIG. 4 is a diagram illustrating an example of a state after an electric field is applied to a heat sink paste (heat dissipation paste) according to an embodiment of the present disclosure.

FIG. 5 is a diagram illustrating another example of a state before an electric field is applied to a heat sink paste (heat dissipation paste) according to an embodiment of the present disclosure.

FIG. 6 is a diagram illustrating another example of a state after an electric field is applied to a heat sink paste (heat dissipation paste) according to an embodiment of the present disclosure.

FIG. 7 is a photograph showing a state before an electric field is applied to a heat sink paste (heat dissipation paste) manufactured according to an embodiment of the present disclosure.

FIG. 8 is a photograph showing a state after an electric field is applied to a heat sink paste (heat dissipation paste) manufactured according to an embodiment of the present disclosure.

### BEST MODE FOR CARRYING OUT THE INVENTION

Hereinafter, embodiments will be described in detail with reference to the accompanying drawings. However, various alterations and modifications may be made to the embodiments. Here, the embodiments are not meant to be limited by the descriptions of the present disclosure. The embodiments should be understood to include all changes, equivalents, and replacements within the idea and the technical scope of the disclosure.

The terminology used herein is for the purpose of describing particular embodiments only and is not intended to be limiting. The singular forms “a”, “an”, and “the” are intended to include the plural forms as well, unless the context clearly indicates otherwise. It will be further understood that the terms “comprises/comprising” and/or “includes/including” when used herein, specify the presence of stated features, integers, steps, operations, elements, and/or components, but do not preclude the presence or addition of one or more other features, integers, steps, operations, elements, components and/or groups thereof.

Unless otherwise defined, all terms including technical and scientific terms used herein have the same meaning as commonly understood by one of ordinary skill in the art to which the embodiments belong. It will be further understood that terms, such as those defined in commonly-used dictionaries, should be interpreted as having a meaning that is consistent with their meaning in the context of the relevant art and will not be interpreted in an idealized or overly formal sense unless expressly so defined herein.

When describing the embodiments with reference to the accompanying drawings, like reference numerals refer to like components and a repeated description related thereto will be omitted. In the description of embodiments, detailed description of well-known related structures or functions will be omitted when it is deemed that such description will cause ambiguous interpretation of the present disclosure.

In addition, terms such as first, second, A, B, (a), (b), and the like may be used to describe components of the embodiments. These terms are used only for the purpose of discriminating one component from another component, and the nature, the sequences, or the orders of the components are not limited by the terms.

A component included in one embodiment and a component having a common function are described using the same names in other embodiments. Unless otherwise mentioned, the descriptions on the embodiments may be applicable to the following embodiments and thus, duplicated descriptions will be omitted for conciseness.

Hereinafter, a heat sink paste (heat dissipation paste), a heat sink film (heat dissipation film), and manufacturing methods thereof will be described in detail with reference to embodiments and drawings. However, the present disclosure is not limited to the embodiments and drawings.

A heat sink paste (heat dissipation paste) according to an embodiment of the present disclosure includes an elastic polymer resin; and conductive particles dispersed in the elastic polymer resin, wherein the conductive particles include solid metal particles and liquid metal particles.

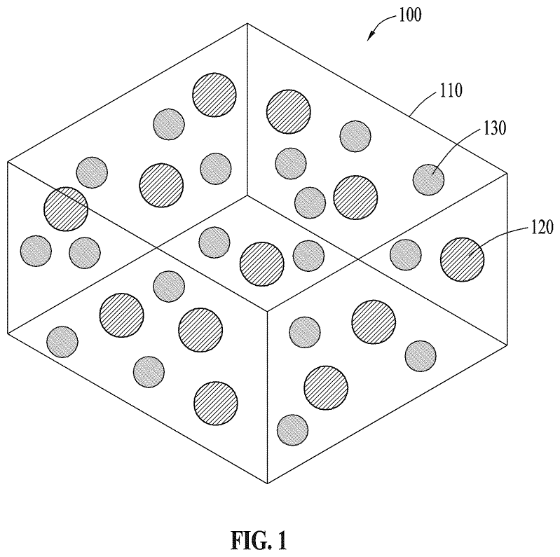

FIG. 1 is a diagram schematically illustrating a heat sink paste (heat dissipation paste) according to an embodiment of the present disclosure.

Referring to FIG. 1, a heat sink paste (heat dissipation paste) 100 according to an embodiment of the present disclosure may include an elastic polymer resin 110, solid metal particles 120, and liquid metal particles 130.

As shown in FIG. 1, the heat sink paste (heat dissipation paste) 100 of the present disclosure is contained in a tetrahedral-shaped container, and embodiments are not limited to a specific shape.

In an embodiment, the elastic polymer resin 110 may be a photocurable resin or a thermosetting resin. Accordingly, the elastic polymer resin 110 may be cured after a voltage is applied. For example, when the elastic polymer resin 110 is prepared and when a voltage is applied in a state in which the solid metal particles 120 and the liquid metal particles 130 are dispersed, curing may be performed with an ultraviolet (UV) lamp, to manufacture a heat sink film (heat dissipation film).

In an embodiment, the elastic polymer resin 110 may include, for example, at least one selected from a group consisting of a polyester acrylate resin, an epoxy acrylate resin, a urethane acrylate resin, a polyether acrylate resin, a silicon acrylate resin, and a vinyl ether resin.

In an embodiment, the elastic polymer resin 110 may include at least one selected from a group consisting of polyacrylate rubber (ACM), ethylene acrylic rubber (AEM), polyurethane (PU), butadiene rubber (BR), chloroprene (or neoprene) rubber (CR), chlorosulfonated polyethylene (CSM), ethylene oxide epichlorohydrin rubber (ECO), ethylene propylene diene rubber (EPDM), perfluoroelastomer (FFKM), fluorocarbon rubber (FKM), fluorosilicone rubber (FVMQ), hydrogenated nitrile butadiene rubber (HNBR), isoprene rubber (IR), butyl rubber (IIR), nitrile butadiene rubber (NBR), natural rubber (NR), polydimethylsiloxane (PDMS), styrene butadiene rubber (SBR), silicone rubber (VMQ). Ecoflex, silicone elastomers, polyimide, polyethylene isopthalate (PEI), polyethylene naphthalate (PEN), polyethylene terephthalate (PET), cellulose, and a styrene-isoprene-styrene copolymer.

In an embodiment, the conductive particles may be in an amount of 10% by weight (wt %) to 90 wt % in the heat sink paste (heat dissipation paste). When the amount of the conductive particles in the heat sink paste (heat dissipation paste) is less than 10 wt %, the thermal conductivity improvement effect may not be sufficient. When the amount of the conductive particles exceeds 90 wt %, phase separation between metal particles and a polymer may occur or a polymer may not be smoothly cured.

In an embodiment, the conductive particles may include the solid metal particles 120 and the liquid metal particles 130 and may be randomly dispersed in the elastic polymer resin 110.

In an embodiment, the solid metal particles 120 may include at least one selected from a group consisting of copper (Cu), gold (Au), platinum (Pt), silver (Ag), iron (Fe), cobalt (Co), nickel (Ni), aluminum (Al), chromium (Cr), tungsten (W), molybdenum (Mo), and titanium (Ti).

In an embodiment, the liquid metal particles 130 may be in a liquid state at room temperature.

In an embodiment, the liquid metal particles 130 may include at least one selected from a group consisting of gallium (Ga), indium (In), tin (Sn), mercury (Hg), lead (Pb), bismuth (Bi), thallium (Tl), zinc (Zn), cadmium (Cd), and an alloy such as a eutectic gallium-indium alloy (EGaIn), a eutectic gallium-indium-tin alloy (Galinstan), gallium/lead (Ga/Pb), gallium/cadmium (Ga/Cd), gallium/bismuth (Ga/Bi), gallium/thallium (Ga/Tl), tin/silver (Sn/Ag), tin/gold (Sn/Au), tin/copper (Sn/Cu), tin/nickel (Sn/Ni), lead/antimony (Pb/Sb), lead/gold (Pb/Au), and lead/cadmium (Pb/Cd).

In an embodiment, a ratio of the solid metal particles 120:the liquid metal particles 130 may in a range of 1:5 to 5:1. When the ratio is less than 1:5, a heat transfer characteristic may be reduced due to a small amount of solid metal particles, or excessive deformation or leakage of liquid metal particles due to external stress may occur. When the ratio exceeds 5:1, an efficiency of aligning particles through an electric field may be reduced, a connectivity between particles may decrease, or rheological properties of a mixed solution of particles and a polymer may be reduced, which may cause a difficulty in processing and a problem of curing (hardness, and solidification).

In an embodiment, the solid metal particles may have a diameter of 50 nanometers (nm) to 50 micrometers (μm). When the diameter of the solid metal particles is less than 50 nm, a larger amount of solvent may be required, and a problem in preparing of particles such as an increase in sonication time may occur. In addition, aggregation of particles may occur, or the heat transfer characteristic may decrease as a thermal contact resistance increases. When the diameter of the solid metal particles exceeds 50 μm, problems in that particles precipitate or that alignment of particles by dielectrophoresis is not smoothly performed may occur.

In an embodiment, the liquid metal particles may have a diameter of 50 nm to 50 μm. When the diameter of the liquid metal particles is less than 50 nm, a larger amount of solvent may be required, and a problem in preparing of particles such as an increase in sonication time may occur. In addition, aggregation of particles may occur, uniformity of particles may decrease, or the heat transfer characteristic may decrease as the thermal contact resistance increases. When the diameter of the liquid metal particles exceeds 50 μm, problems in that particles precipitate or that alignment of particles by dielectrophoresis is not smoothly performed may occur.

A heat sink paste (heat dissipation paste) according to an embodiment of the present disclosure may be used as a heat dissipation material having an excellent thermal conductivity and elasticity by curing a paste state according to a desired purpose of use, because conductive particles in an elastic polymer resin may be arranged with directivity when an electric field is applied.

A heat sink film (heat dissipation film) according to an embodiment of the present disclosure may include an elastic polymer; and conductive particles embedded in the elastic polymer. The conductive particles may include solid metal particles and liquid metal particles, and the solid metal particles and the liquid metal particles may be arranged in a heat transfer direction by applying an electric field.

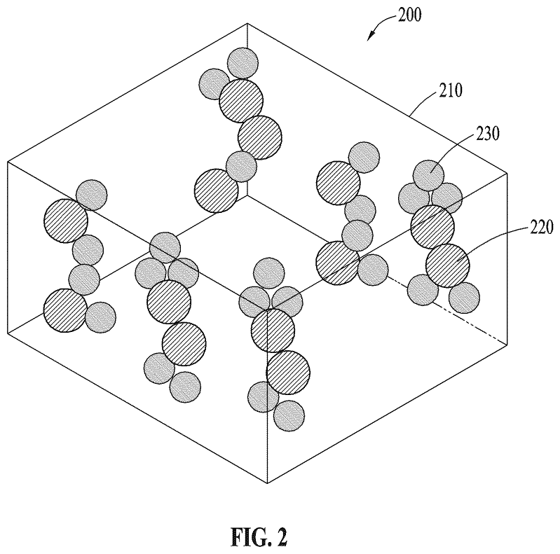

FIG. 2 is a diagram schematically illustrating a heat sink film (heat dissipation film) according to an embodiment of the present disclosure.

Referring to FIG. 2, a heat sink film (heat dissipation film) 200 according to an embodiment of the present disclosure may include an elastic polymer 210, solid metal particles 220, and liquid metal particles 230.

The heat sink film (heat dissipation film) according to an embodiment of the present disclosure may form a particle chain while aligning particles with directivity based on a particle alignment principle such as dielectrophoresis, by applying an electric field to the heat sink paste (heat dissipation paste) according to an embodiment of the present disclosure.

In an embodiment, the elastic polymer 210 may be cured through a process of curing a photocurable resin or a thermosetting resin.

In an embodiment, the elastic polymer 210 may include, for example, at least one selected from a group consisting of a polyester acrylate resin, an epoxy acrylate resin, a urethane acrylate resin, a polyether acrylate resin, a silicon acrylate resin, and a vinyl ether resin.

In an embodiment, the elastic polymer 210 may include at least one selected from a group consisting of polyacrylate rubber (ACM), ethylene acrylic rubber (AEM), polyurethane (PU), butadiene rubber (BR), chloroprene (or neoprene) rubber (CR), chlorosulfonated polyethylene (CSM), ethylene oxide epichlorohydrin rubber (ECO), ethylene propylene diene rubber (EPDM), perfluoroelastomer (FFKM), fluorocarbon rubber (FKM), fluorosilicone rubber (FVMQ), hydrogenated nitrile butadiene rubber (HNBR), isoprene rubber (IR), butyl rubber (IIR), nitrile butadiene rubber (NBR), natural rubber (NR), polydimethylsiloxane (PDMS), styrene butadiene rubber (SBR), silicone rubber (VMQ). Ecoflex, silicone elastomers, polyimide, polyethylene isopthalate (PEI), polyethylene naphthalate (PEN), polyethylene terephthalate (PET), cellulose, and a styrene-isoprene-styrene copolymer.

In an embodiment, the heat sink film (heat dissipation film) 200 may form a chain between particles while aligning solid metal particles 220 and liquid metal particles 230, which are conductive particles in the elastic polymer 210, with directivity based on the dielectrophoresis principle, by applying an electric field. By the above chain, a path through which heat may be dissipated and transferred may be formed.

In an embodiment, the solid metal particles 220 may include at least one selected from a group consisting of copper (Cu), gold (Au), platinum (Pt), silver (Ag), iron (Fe), cobalt (Co), nickel (Ni), aluminum (Al), chromium (Cr), tungsten (W), molybdenum (Mo), and titanium (Ti).

In an embodiment, the liquid metal particles 230 may be in a liquid state at room temperature.

In an embodiment, the liquid metal particles 230 may include at least one selected from a group consisting of a single metal such as gallium (Ga), indium (In), tin (Sn), mercury (Hg), lead (Pb), bismuth (Bi), thallium (Tl), zinc (Zn), cadmium (Cd), and the like; and an alloy such as a eutectic gallium-indium alloy (EGaIn), a eutectic gallium-indium-tin alloy (Galinstan), gallium/lead (Ga/Pb), gallium/cadmium (Ga/Cd), gallium/bismuth (Ga/Bi), gallium/thallium (Ga/Tl), tin/silver (Sn/Ag), tin/gold (Sn/Au), tin/copper (Sn/Cu), tin/nickel (Sn/Ni), lead/antimony (Pb/Sb), lead/gold (Pb/Au), and lead/cadmium (Pb/Cd).

In an embodiment, a ratio of the solid metal particles 120:the liquid metal particles 130 may in a range of 1:5 to 5:1. When the ratio is less than 1:5, a heat transfer characteristic may be reduced due to a small amount of solid metal particles, or excessive deformation or leakage of liquid metal particles due to external stress may occur. When the ratio exceeds 5:1, an efficiency of aligning particles through an electric field may be reduced, a connectivity between particles may decrease, or rheological properties of a mixed solution of particles and a polymer may be reduced, which may cause a difficulty in processing and a problem of curing (hardness, and solidification).

In an embodiment, the solid metal particles may have a diameter of 50 nm to 50 μm. When the diameter of the solid metal particles is less than 50 nm, a larger amount of solvent may be required, and a problem in preparing of particles such as an increase in sonication time may occur. In addition, aggregation of particles may occur, or the heat transfer characteristic may decrease as a thermal contact resistance increases. When the diameter of the solid metal particles exceeds 50 μm, problems in that particles precipitate or that alignment of particles by dielectrophoresis is not smoothly performed may occur.

In an embodiment, the liquid metal particles may have a diameter of 50 nm to 50 μm. When the diameter of the liquid metal particles is less than 50 nm, a larger amount of solvent may be required, and a problem in preparing of particles such as an increase in sonication time may occur. In addition, aggregation of particles may occur, uniformity of particles may decrease, or the heat transfer characteristic may decrease as the thermal contact resistance increases. When the diameter of the liquid metal particles exceeds 50 μm, problems in that particles precipitate or that alignment of particles by dielectrophoresis is not smoothly performed may occur.

A heat sink film (heat dissipation film) according to an embodiment of the present disclosure may have an excellent thermal conductivity even at a high strain rate and may be changeable to a heat dissipation material with an elasticity, and thus it is possible to apply the heat sink film (heat dissipation film) to various flexible electronic devices or wearable displays.

A method of manufacturing a heat sink film (heat dissipation film) according to another embodiment of the present disclosure includes steps of: applying an electric field to a heat sink paste (heat dissipation paste) according to an embodiment of the present disclosure; and curing the elastic polymer resin.

A method of manufacturing a heat sink film (heat dissipation film) according to an embodiment of the present disclosure may include a step of applying an electric field, and a step of performing curing.

In an embodiment, in the step of applying the electric field, the electric field may be applied to an elastic polymer resin in which solid metal particles and liquid metal particles are dispersed, that is, a heat sink paste (heat dissipation paste) according to an embodiment of the present disclosure.

In an embodiment, the electric field may be an alternating current (AC) voltage.

In an embodiment, the solid metal particles, the liquid metal particles, and the elastic polymer resin are the same as those described above, and accordingly, redundant description thereof is omitted herein.

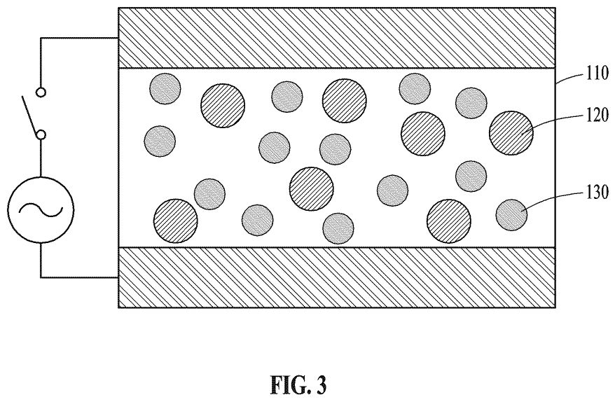

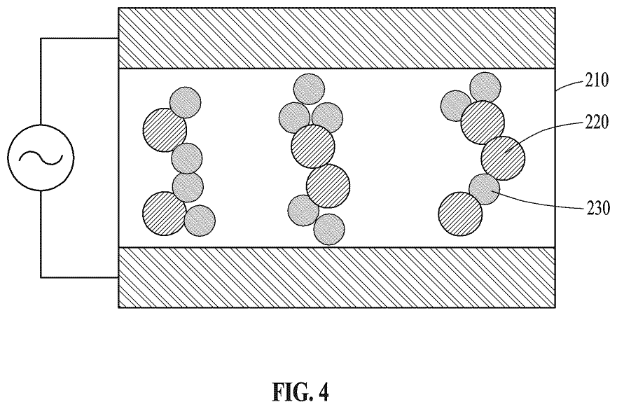

FIG. 3 is a diagram illustrating an example of a state before an electric field is applied to a heat sink paste (heat dissipation paste) according to an embodiment of the present disclosure, and FIG. 4 is a diagram illustrating an example of a state after an electric field is applied to a heat sink paste (heat dissipation paste) according to an embodiment of the present disclosure.

Referring to FIGS. 3 and 4, the heat sink paste (heat dissipation paste) of the present disclosure may be placed between an upper electrode and a lower electrode and an AC voltage may be applied. As shown in FIG. 3, solid metal particles and liquid metal particles are initially randomly dispersed in an elastic polymer resin matrix. When the AC voltage is applied, a particle chain may be formed while particles are being aligned with directivity based on the principle such as dielectrophoresis, as shown in FIG. 4.

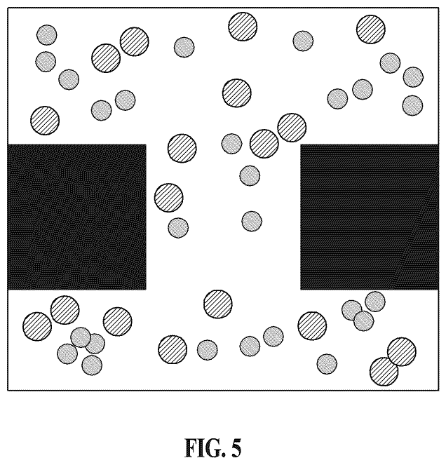

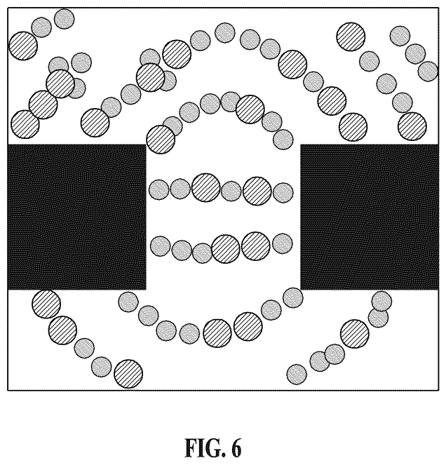

FIG. 5 is a diagram illustrating another example of a state before an electric field is applied to a heat sink paste (heat dissipation paste) according to an embodiment of the present disclosure, and FIG. 6 is a diagram illustrating another example of a state after an electric field is applied to a heat sink paste (heat dissipation paste) according to an embodiment of the present disclosure.

Referring to FIGS. 5 and 6, two electrodes horizontally face each other. The heat sink paste (heat dissipation paste) of the present disclosure may be placed between the two electrodes and an AC voltage may be applied. As shown in FIG. 5, solid metal particles and liquid metal particles are initially randomly dispersed in an elastic polymer resin matrix. When the AC voltage is applied, a particle chain may be formed while particles are being aligned with directivity based on the principle such as dielectrophoresis, as shown in FIG. 6.

In an embodiment, in the step of applying the electric field, the electric field may be applied at an intensity ranging from 10 volts per millimeter (V/mm) to 600 V/mm for 1 second to 180 minutes. When the voltage is less than 10 V/mm and when an amount of time to apply the electric field is less than 1 second, particles may hardly be aligned due to a low intensity of the electric field. When the voltage exceeds 600 V/mm and when the amount of time to apply the electric field exceeds 180 minutes, a thermal or electrical breakdown phenomenon of a polymer may occur or a problem in stability due to overheating or ignition may occur.

The particle alignment effect may vary depending on a distance between electrodes even though the electric field is applied at the same voltage.

In an embodiment, in the step of applying the electric field, a frequency ranging from 100 hertz (Hz) to 10 megahertz (MHz) may be applied for 1 second to 180 minutes. When the frequency is less than 100 Hz, an electrothermal effect or an electrohydrodynamics effect may occur, which may interfere with an alignment of particles or damage a surface of an electrode. When the frequency exceeds 10 MHZ, particles may not be effectively aligned by an electric field.

In an embodiment, in the step of performing the curing, the elastic polymer resin in the heat sink paste (heat dissipation paste) may be cured.

In a state in which the solid metal particles and the liquid metal particles are aligned, UV rays may be irradiated to the elastic polymer resin using a UV lamp, or heat may be applied to the elastic polymer resin using a heat curing lamp. Thus, a heat sink film (heat dissipation film) in a state in which the solid metal particles and the liquid metal particles are arranged in a thickness direction may be manufactured.

For example, a polymer may be cured by a simple method such as irradiation with a UV lamp. In addition, a UV curing process may be performed together in a state in which a voltage is applied to the elastic polymer resin. In addition, a UV-curable polymer resin may have an advantage of a small strain of a film during a curing process in comparison to a thermally curable polymer resin.

A method of manufacturing a heat sink film (heat dissipation film) according to an embodiment of the present disclosure may be used to manufacture a heat sink film (heat dissipation film) with an excellent heat dissipation effect and a maximized thermal conductivity, by arranging conductive particles with directivity, because it is possible to simply, quickly, and effectively arrange the particles through an electric field.

By the method of manufacturing the heat sink film (heat dissipation film) according to an embodiment of the present disclosure, a thermal interface material (TIM) having a high thermal conductivity and an elasticity may be prepared.

Hereinafter, the present disclosure will be described in detail with reference to the following examples and comparative examples. However, the technical idea of the present disclosure is not limited or restricted thereto.

### Examples

In 90 wt % of polydimethylsiloxane (PDMS) as an elastic polymer resin, copper (Cu) as solid metal particles and a eutectic gallium-indium alloy (EGaIn) as liquid metal particles were mixed in a ratio of 1:4 so that the total amount of metal particles was 10 wt %, to manufacture a heat sink paste (heat dissipation paste).

The manufactured heat sink paste (heat dissipation paste) was placed between two electrode plates and a voltage was applied at an electric field of 70 V/mm and a frequency of 100 kHz for 15 minutes so that particles were aligned and arranged in the elastic polymer resin.

Subsequently, the elastic polymer resin was cured using a UV lamp, to manufacture a heat sink film (heat dissipation film).

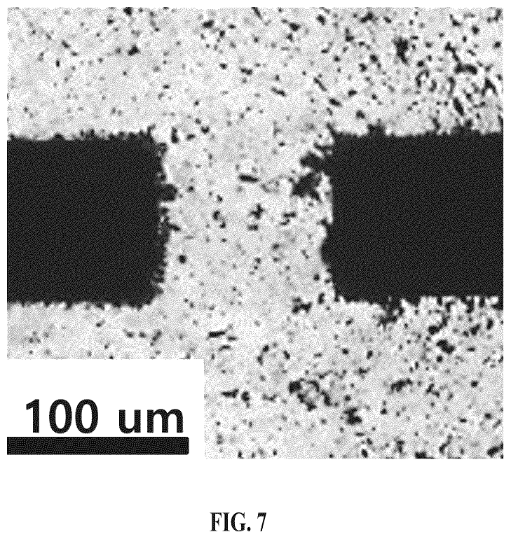

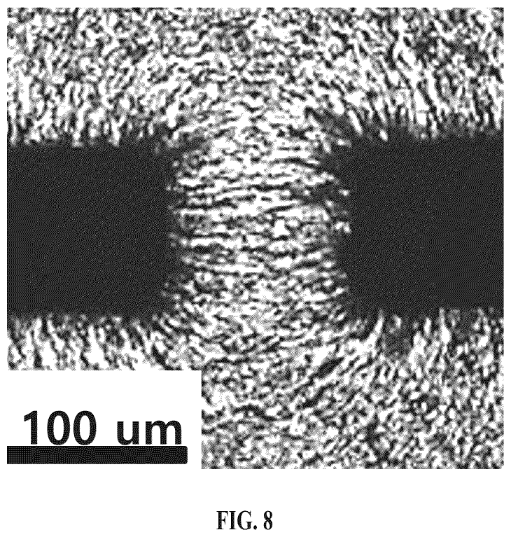

FIG. 7 is a photograph showing a state before an electric field is applied to a heat sink paste (heat dissipation paste) manufactured according to an embodiment of the present disclosure, and FIG. 8 is a photograph showing a state after an electric field is applied to a heat sink paste (heat dissipation paste) manufactured according to an embodiment of the present disclosure.

Referring to FIGS. 7 and 8, it can be confirmed that solid metal particles, and liquid metal particles form chains when an electric field is applied.

### Experimental Example 1: Measurement of Thermal Diffusivity

To identify a thermal diffusivity of a heat sink film (heat dissipation film) according to an embodiment of the present disclosure, each of voltages of 0, 3, and 5 kV/cm was applied to a heat sink film (heat dissipation film) with a straight line pattern, and the thermal diffusivity associated with a volume ratio between solid metal particles and liquid metal particles was measured.

It was confirmed that when a voltage was not applied, there was little difference in thermal diffusivity, however, the thermal diffusivity increased in response to an increase in the voltage and the amount of solid metal particles and liquid metal particles.

### Experimental Example 2: Measurement of Thermal Conductivity

To identify a thermal conductivity of a heat sink film (heat dissipation film) according to an embodiment of the present disclosure, each of voltages of 0, 3, and 5 kV/cm was applied to a heat sink film (heat dissipation film) with a straight line pattern, and the thermal conductivity associated with the amount of solid metal particles and liquid metal particles was measured.

It can be confirmed that when a voltage was not applied, there was little difference in thermal conductivity, however, the thermal conductivity increased in response to an increase in the voltage and the amount of solid metal particles and liquid metal particles.

It was confirmed that a wire and a chain between metal particles in an elastic polymer function as paths for transferring heat.

While the embodiments are described with reference to drawings, it will be apparent to one of ordinary skill in the art that various alterations and modifications in form and details may be made in these embodiments without departing from the spirit and scope of the claims and their equivalents. For example, suitable results may be achieved if the described techniques are performed in a different order, and/or if components in a described system, architecture, device, or circuit are combined in a different manner, and/or replaced or supplemented by other components or their equivalents.

Therefore, other implementations, other embodiments, and equivalents to the claims are also within the scope of the following claims.

1. A heat sink paste (heat dissipation paste) comprising:
an elastic polymer resin; and
conductive particles dispersed in the elastic polymer resin,
wherein the conductive particles comprise solid metal particles and liquid metal particles.

2. The heat sink paste (heat dissipation paste) of claim 1, wherein the elastic polymer resin comprises at least one selected from a group consisting of polyacrylate rubber (ACM), ethylene acrylic rubber (AEM), polyurethane (PU), butadiene rubber (BR), chloroprene (or neoprene) rubber (CR), chlorosulfonated polyethylene (CSM), ethylene oxide epichlorohydrin rubber (ECO), ethylene propylene diene rubber (EPDM), perfluoroelastomer (FFKM), fluorocarbon rubber (FKM), fluorosilicone rubber (FVMQ), hydrogenated nitrile butadiene rubber (HNBR), isoprene rubber (IR), butyl rubber (IIR), nitrile butadiene rubber (NBR), natural rubber (NR), polydimethylsiloxane (PDMS), styrene butadiene rubber (SBR), silicone rubber (VMQ), Ecoflex, silicone elastomers, polyimide, polyethylene isopthalate (PEI), polyethylene naphthalate (PEN), polyethylene terephthalate (PET), cellulose, and a styrene-isoprene-styrene copolymer.

3. The heat sink paste (heat dissipation paste) of claim 1, wherein the solid metal particles comprise at least one selected from a group consisting of copper (Cu), gold (Au), platinum (Pt), silver (Ag), iron (Fe), cobalt (Co), nickel (Ni), aluminum (Al), chromium (Cr), tungsten (W), molybdenum (Mo), and titanium (Ti).

4. The heat sink paste (heat dissipation paste) of claim 1, wherein the liquid metal particles comprise at least one selected from a group consisting of gallium (Ga), indium (In), tin (Sn), mercury (Hg), lead (Pb), bismuth (Bi), thallium (TI), zinc (Zn), cadmium (Cd), a eutectic gallium-indium alloy (EGaIn), a eutectic gallium-indium-tin alloy (Galinstan), gallium/lead (Ga/Pb), gallium/cadmium (Ga/Cd), gallium/bismuth (Ga/Bi), gallium/thallium (Ga/Tl), tin/silver (Sn/Ag), tin/gold (Sn/Au), tin/copper (Sn/Cu), tin/nickel (Sn/Ni), lead/antimony (Pb/Sb), lead/gold (Pb/Au), and lead/cadmium (Pb/Cd).

5. The heat sink paste (heat dissipation paste) of claim 1, wherein
the conductive particles are in an amount of 10% by weight (wt %) to 90 wt % in the heat sink paste (heat dissipation paste), and
a ratio of the solid metal particles:the liquid metal particles is in a range of 1:5 to 5:1.

6. The heat sink paste (heat dissipation paste) of claim 1, wherein
the solid metal particles have a diameter of 50 nanometers (nm) to 50 micrometers (μm), and
the liquid metal particles have a diameter of 50 nm to 50 μm.

7. A heat sink film (heat dissipation film) comprising:
an elastic polymer; and
conductive particles embedded in the elastic polymer,
wherein the conductive particles comprise solid metal particles and liquid metal particles, and the solid metal particles and the liquid metal particles are arranged in a heat transfer direction by applying an electric field.

8. A method of manufacturing a heat sink film (heat dissipation film), the method comprising steps:
applying an electric field to the heat sink paste (heat dissipation paste) of claim 1; and
curing the elastic polymer resin.

9. The method of claim 8, wherein in the step of applying the electric field, the electric field is applied at an intensity ranging from 10 volts per millimeter (V/mm) to 600 V/mm for 1 second to 180 minutes.

10. The method of claim 8, wherein in the step of applying the electric field, a frequency ranging from 100 hertz (Hz) to 10 megahertz (MHz) is applied for 1 second to 180 minutes.
